(19) United States
(12) Patent Application Publication
(10) Pub. No.: US 2026/0169064 A1
(43) Pub. Date: Jun. 18, 2026

(54) METHODS, SYSTEMS, AND COMPUTER READABLE MEDIA FOR TESTING THE PERFORMANCE AND RELIABILITY OF A DEVICE OR SYSTEM UNDER TEST (SUT) USING REAL AND EMULATED PROCESSING RANKS WITHIN A DATA CENTER ENVIRONMENT

(71) Applicant: Keysight Technologies, Inc., Santa Rosa, CA (US)

(72) Inventor: Konstantin Belov, Thousand Oaks, CA (US)

(21) Appl. No.: 19/532,763

(22) Filed: Feb. 6, 2026

(51) Int. Cl. G01R 31/317; G06N 20/00

(52) U.S. Cl. CPC G01R 31/31718; G01R 31/31724; G06N 20/00

(57) ABSTRACT

Methods, systems, and computer readable media for testing the performance and reliability of a device or system under test (SUT) using real and emulated processing ranks within a data center environment are disclosed. According to one aspect, a method for testing the performance and reliability of a SUT includes instantiating a machine learning (ML)-framework-based plugin, including an emulator configured for emulating processing units, and communicating, from a controller on a test system, a configuration of the ML-framework-based plugin to non-emulated processing units on the SUT. The method further includes performing a test of the SUT by executing a ML workload on the non-emulated processing units, emulating execution of the ML workload on the emulated processing units, exchanging packets associated with the execution of the ML workload between the non-emulated processing units and the ML-framework-based plugin, and monitoring performance of the non-emulated processing units in executing the machine learning workload.

### TECHNICAL FIELD

The subject matter described herein relates to testing of a rack of processing units performing a machine learning workload. More particularly, the subject matter described herein relates to methods, systems, and computer readable media for testing the performance and reliability of a device or system under test (SUT) using real and emulated processing ranks within a data center environment.

### BACKGROUND

Moving from server manufacturing to rack and multi-rack level manufacturing requires rapid progress in components which requires fast turnaround times. There are an increased complexity of racks with a variety of interconnects (nvlink, ualink, uet, etc.) and rapidly increasing power demands. Furthermore, with the rising complexity of AI/ML systems, there is a high cost of failures in production deployment when manufacturing test systems. Simple jobs rarely encounter errors, but complex jobs require exercising all components of a system together (such as accelerators, intra-rack interconnects, inter-rack networking, memory, storage, etc.) in a realistic pattern (to measure utilization, power consumption, temperature, etc.), which depends on the AI workload/models used by the end customer.

The challenge at the manufacturing stage with running real AI workloads is that large-scale workloads require building mini datacenters as testing a single server or rack in isolation may be insufficient to exercise all components. Running actual workloads is difficult as it requires access to models and special expertise and as a result, it is very costly, especially in earlier stages such as design cycle. Testing individual elements of a system is necessary, but the ultimate challenge is exercising everything the same way as it would be exercised in real life. For example, if you run your own software, how can you convince the user that it's accurate? Likewise, if you run user's custom software, how would you show the problem to the vendor if the software cannot be distributed?

Accordingly, in light of these disadvantages associated with AI/ML model testing, there exists a need for executing real AI workload tools on a real rack being tested, connecting it to a much smaller system representing other racks in a cluster, and assessing system behavior with a real usage pattern in real time, not in simulation. Thus, there exists a need for methods, systems, and computer readable media for running real model training on a subset of a system and substituting the rest of the real system with emulated racks to make the model believe it is running everywhere.

### SUMMARY

The subject matter described herein provides architectures and techniques for a test system that includes a controller that is capable of making it appear to a device or system under test that it looks as if the rack has more servers than it actually has and to make it look as if there are other ranks surrounding the real rack. At a high level, the test system complements an end user's real physical infrastructure with a custom platform to make PyTorch AI training jobs see a larger cluster than what the physical infrastructure is connected to, leverage popular AI models from the library provided by our platform or work with our team to add a custom model to the pool, run real PyTorch training on the model, and exercise all elements of their rack.

A deep learning framework orchestrates model execution across multiple ranks, where each rank performs tensor operations on compute devices, such as CPUs, GPUs, and accelerators (e.g., CUDA-enabled GPUs, Gaudi, MTIA). The framework then distributes work between ranks using parallelism strategies such as DDP and FSDP, which request collective operations from collective communication libraries (e.g., NCCL, Gloo) operating over defined process groups. These collective libraries implement communication algorithms and utilize underlying transport protocols (such as TCP, InfiniBand, NVLink, etc.) to move runtime tensor data directly between ranks. Finally, separate from the data path, coordination and rendezvous between processes is handled via control-plane mechanisms such as TCPStore.

Backends/process groups can (and do) utilize their own control protocols, so interoperability with a rank is not just a matter of data traffic and TCP Store. However, it just needs to report enough to TCP Store to convince it that all ranks are present and have the real ranks retrieve necessary information to initialize collective communication, then a real rank does the real job, just on partially fake data as the fake transport only pretends to send data and pretends to have received the data (as it knows tensor shape). This allows it to exercise computations faithfully (minus the computations from the collectives themselves, although it can be added), but the traffic timing is unrealistic (as no traffic is being sent or received).

Collective Communication Library (CCL) uses a non-trivial amount of control traffic (aside from flow control) which initially appears difficult to mimic and maintain version to version. By leveraging CCL in a fake process group and actually run the collectives, there is an adequate GPU utilization on the real rank, but the problem of control traffic is still present. Therefore, a framework doesn't need to be present on the fake ranks, but CCL does.

Similarly, if the collectives are still ran, but this time instead of using CCL in the fake process group, custom ibverbs are coded there is no problem with CCL control traffic, but GPU utilization is lower as no compute unified device architecture (CUDA) and/or CUDA cores are used in collectives. Ibverbs are what allow processes to use remote direct memory access (RDMA) verbs to perform high-throughput, low-latency network operations. However, coding ibverbs as efficiently as CCL was beyond proof of concept. It's possible to call CUDA from process the custom process group. It would eliminate both control and traffic problem (as no CCL) and get adequate GPU utilization, but it would need to be as efficient as CCL at doing so. Finally, if CCL is kept, but substitute its IB transport with the custom IB transport from the previous test case causes the amount of control plane traffic that needs to be understood decreases, but it still needs to be understood.

Further experimentation with the proof of concept established that providing a custom CCL plugin to run on real ranks and interoperating with TCPStore and CCL process group control traffic, would likely be the simplest proof of concept if able to be implemented and is the subject of this application.

A method for testing the performance and reliability of a device or system under test (SUT) using real and emulated processing ranks within a data center environment includes connecting a test system to a SUT, the test system includes a controller and the SUT includes non-emulated processing units, instantiating a machine learning (ML)-framework-based plugin including an emulator configured for emulating processing units, and communicating, from the controller on the test system, a configuration of the ML-framework-based plugin to non-emulated processing unit that includes a collectives parameter indicating a quantity and rank information of the emulated processing units. The method further includes performing a test of the SUT by executing a ML workload on the non-emulated processing units, emulating execution of the ML workload on the emulated processing units, exchanging packets associated with the execution of the ML workload between the non-emulated processing units and the ML-framework-based plugin, and monitoring performance of the non-emulated processing units in executing the machine learning workload.

According to another aspect of the subject matter described herein, including instantiating, on the SUT, an emulated transport plugin, wherein instantiating the ML-framework-based plugin includes instantiating the ML-framework-based plugin on the SUT and exchanging the packets includes emulating, using the emulated transport plugin, transport of the packets over a network.

According to another aspect of the subject matter described herein, the emulated transport plugin includes a collective communications library (CCL) plugin.

According to another aspect of the subject matter described herein, including using the emulated transport plugin to control an execution graph implemented by the emulated and non-emulated processing units.

According to another aspect of the subject matter described herein, instantiating the ML-framework-based plugin includes instantiating the ML-framework-based plugin on the test system and exchanging the packets includes exchanging packets between the test system and the non-emulated processing units over a network.

According to another aspect of the subject matter described herein, including adjusting the collectives parameter during the execution of the machine learning workload.

According to another aspect of the subject matter described herein, adjusting the collectives parameter includes changing the quantity of emulated processing units.

According to another aspect of the subject matter described herein, the ML-framework-based plugin includes a PyTorch plugin, a Scikit-learning plugin, or a Tensorflow plugin.

According to another aspect of the subject matter described herein, the ML-framework plugin includes the PyTorch plugin and wherein emulating the processing units includes interacting with a TCPStore.

According to another aspect of the subject matter described herein, emulating the processing units includes emulating at least one rack of processing units that, when combined with the non-emulated processing units, form a cluster of processing units.

According to another aspect of the subject matter described herein, a system for testing the performance and reliability of a device or system under test (SUT) using real and emulated processing ranks within a data center environment includes a test system including a controller, at least one processor and a memory, and a connector for connecting to an electrical connector associated with a SUT. The system is configured to perform a test of the SUT including computer-executable instructions stored in the memory and executable by the at least one processor by instantiating a machine learning (ML)-framework-based plugin, the ML-framework-based plugin including an emulator configured for emulating processing units, and communicating, from the controller on the test system, a configuration of the ML-framework-based plugin to non-emulated processing units, wherein the configuration includes a collectives parameter indicating a quantity and rank information of the emulated processing units. The system is further configured for performing the test of the SUT by executing a ML workload on the non-emulated processing units, emulating execution of the ML workload on the emulated processing units, exchanging packets associated with the execution of the ML workload between the non-emulated processing units and the ML-framework-based plugin, and monitoring performance of the non-emulated processing units in executing the machine learning workload.

According to another aspect of the subject matter described herein, configured for instantiating, on the SUT, an emulated transport plugin, wherein instantiating the ML-framework-based plugin includes instantiating the ML-framework-based plugin on the SUT and exchanging the packets includes emulating, using the emulated transport plugin, transport of the packets over a network.

According to another aspect of the subject matter described herein, the emulated transport plugin includes a collective communications library (CCL) plugin.

According to another aspect of the subject matter described herein, configured for using the emulated transport plugin to control an execution graph implemented by the emulated and non-emulated processing units.

According to another aspect of the subject matter described herein, instantiating the ML-framework-based plugin includes instantiating the ML-framework-based plugin on the test system and exchanging the packets includes exchanging packets between the test system and the non-emulated processing units over a network.

According to another aspect of the subject matter described herein, configured for adjusting the collectives parameter during the execution of the machine learning workload and includes changing the quantity of emulated processing units.

According to another aspect of the subject matter described herein, the ML-framework-based plugin includes a PyTorch plugin, a Scikit-learning plugin, or a Tensorflow plugin.

According to another aspect of the subject matter described herein, the ML-framework plugin includes the PyTorch plugin and wherein emulating the processing units includes interacting with a TCPStore.

According to another aspect of the subject matter described herein, emulating the processing units includes emulating at least one rack of processing units that, when combined with the non-emulated processing units, form a cluster of processing units.

According to another aspect of the subject matter described herein, one or more non-transitory computer readable media having stored thereon executable instructions that when executed by one or more processors of one or more computers control the one or more computers to perform steps is provided. The steps include instantiating a machine learning (ML)-framework-based plugin including an emulator configured for emulating processing units, and communicating, from a controller on a test system, a configuration of the ML-framework-based plugin to non-emulated processing units on a SUT, wherein the configuration includes a collectives parameter indicating a quantity and rank information of the emulated processing units. The steps further include performing a test of the SUT by executing a ML workload on the non-emulated processing units, emulating execution of the ML workload on the emulated processing units, exchanging packets associated with the execution of the ML workload between the non-emulated processing units and the ML-framework-based plugin, and monitoring performance of the non-emulated processing units in executing the machine learning workload.

The subject matter described herein for testing the performance and reliability of a device or system under test (SUT) using real and emulated processing ranks within a data center environment may be implemented in hardware, software, firmware, or any combination thereof. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIGS. 1A and 1B are graphs illustrating the results of testing alternative proof of concepts to arrive at a solution for large scale AI/ML model testing according to an aspect of the subject matter described herein;

FIGS. 2A and 2B are block diagrams illustrating a system for testing the performance and reliability of a device or system under test (SUT) using real and emulated processing ranks with emulated and real network communication respectively according to an aspect of the subject matter described herein;

FIGS. 3A and 3B are flow charts illustrating an exemplary process for testing the performance and reliability of a device or system under test (SUT) using real and emulated processing ranks with emulated network communication and real network communication respectively according to an aspect of the subject matter described herein;

FIGS. 4A, 4B, and 4C are flow charts illustrating an exemplary process for testing the performance and reliability of a device or system under test (SUT) using real and emulated processing ranks using a collective graph, a profile trace, and a scaled profile trace respectively according to an aspect of the subject matter described herein;

FIGS. 5A, 5B, 5C, and 5D are diagrams comparing the accuracy of a system that consists of two real ranks and two emulated ranks with a system consisting of four real ranks in GPU utilization, power consumption, temperature, and NVLink data transfers according to an aspect of the subject matter described herein;

FIGS. 6A, 6B, 6C, and 6D are diagrams comparing the results of a system utilizing four real ranks and twelve emulated ranks that has NVLink enabled with a system utilizing four real ranks and twelve emulated ranks that has NVLink disabled in GPU utilization, power consumption, temperature, and data transfers according to an aspect of the subject matter described herein; and

FIGS. 7A, 7B, and 7C are diagrams illustrating the GPU utilization, power consumption, and temperature of a system with one real rank and 63 emulated ranks respectively according to an aspect of the subject matter described herein.

### DETAILED DESCRIPTION

The subject matter described herein includes systems, methods, and computer readable media for testing the performance and reliability of a device or system under test (SUT) using real and emulated processing ranks within a data center environment. The approach includes connecting a test system to a SUT, the test system includes a controller and the SUT includes non-emulated processing units, instantiating a machine learning (ML)-framework-based plugin including an emulator configured for emulating processing units, and communicating, from the controller on the test system, a configuration of the ML-framework-based plugin to non-emulated processing unit that includes a collectives parameter indicating a quantity and rank information of the emulated processing units. The approach further includes performing a test of the SUT by executing a ML workload on the non-emulated processing units, emulating execution of the ML workload on the emulated processing units, exchanging packets associated with the execution of the ML workload between the non-emulated processing units and the ML-framework-based plugin, and monitoring performance of the non-emulated processing units in executing the machine learning workload.

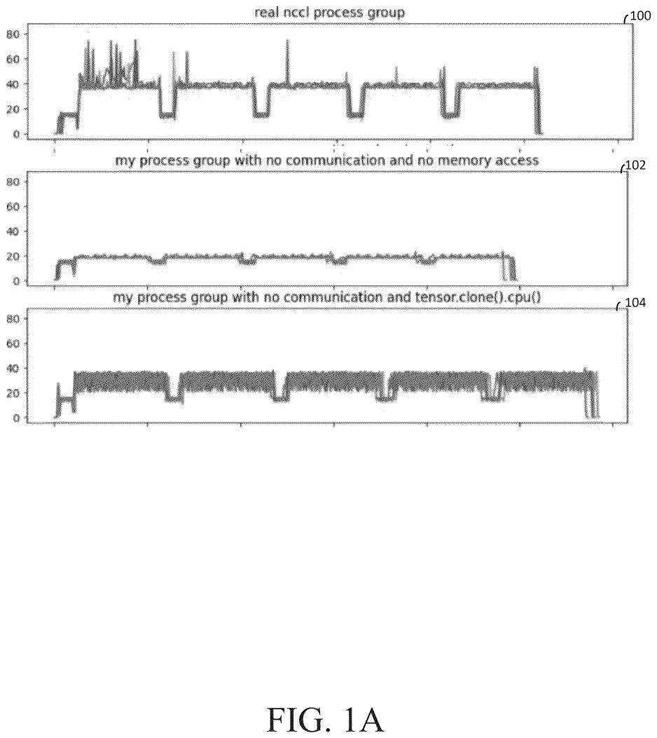

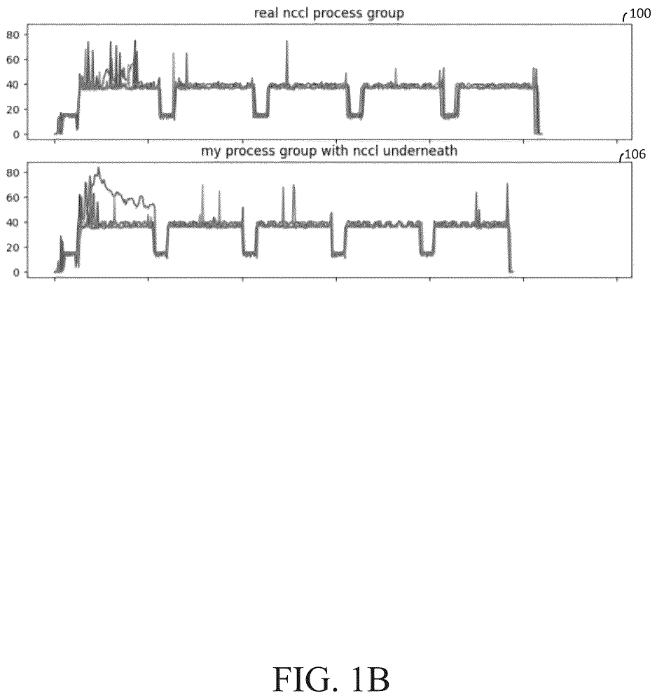

FIGS. 1A and 1B are diagrams illustrating the results of testing alternative proof of concepts to arrive at a solution for largescale AI/ML model testing. Referring to FIG. 1A, graph 100 shows CPU utilization of ResNet50 (a deep convolutional neural network architecture used primarily for image recognition)operating on a real image dataset with the percentage of GPU utilization on the Y-axis and 5 epochs on the X-axis. Graph 102 shows the percentage of GPU utilization when a custom process group with no communication and no memory access is executed while graph 104 shows the percentage of GPU utilization when a custom process group with no communication and a tensor clone for memory access is executed. 102 and 104 when compared to 100 illustrate that merely adding memory access extends JCT in a measurable way.

Referring to FIG. 1B, again, results from the real CCL process group are illustrated by graph 100, but graph 106 shows a custom process group where this time CCL is actually executed on the collectives. Graphs 102, 104, and 106 illustrate that for adequate GPU utilization on a real rank, control traffic is always present. Graphs 102, 104, and 106 also illustrate that for proper GPU utilization on a real rank, CCL needs to be present on the fake ranks. Further experimentation with the proof of concept established that providing a custom CCL plugin to run on real ranks and interoperating with TCPStore and CCL process group control traffic, would likely be the simplest proof of concept if able to be implemented and is the subject of this application.

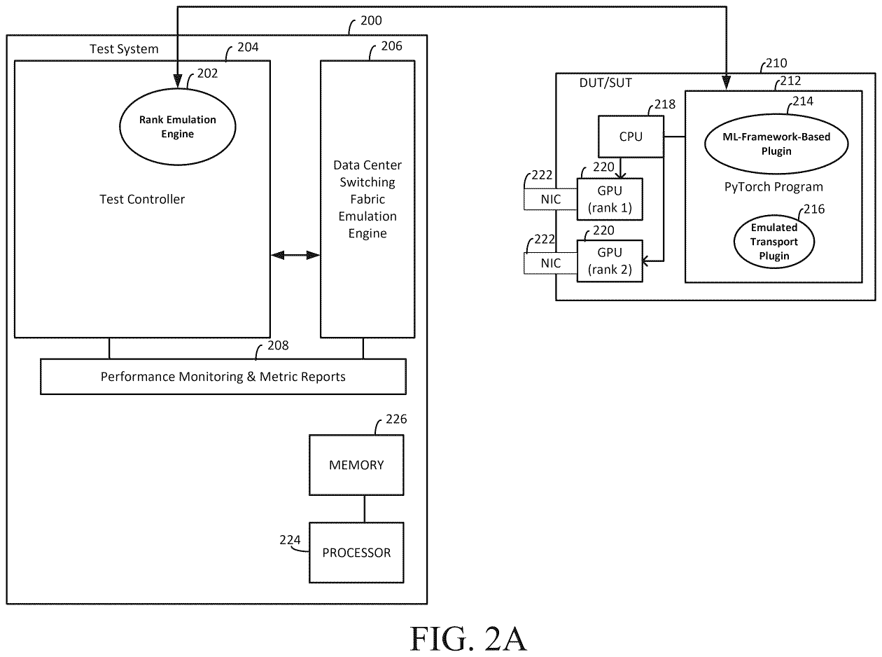

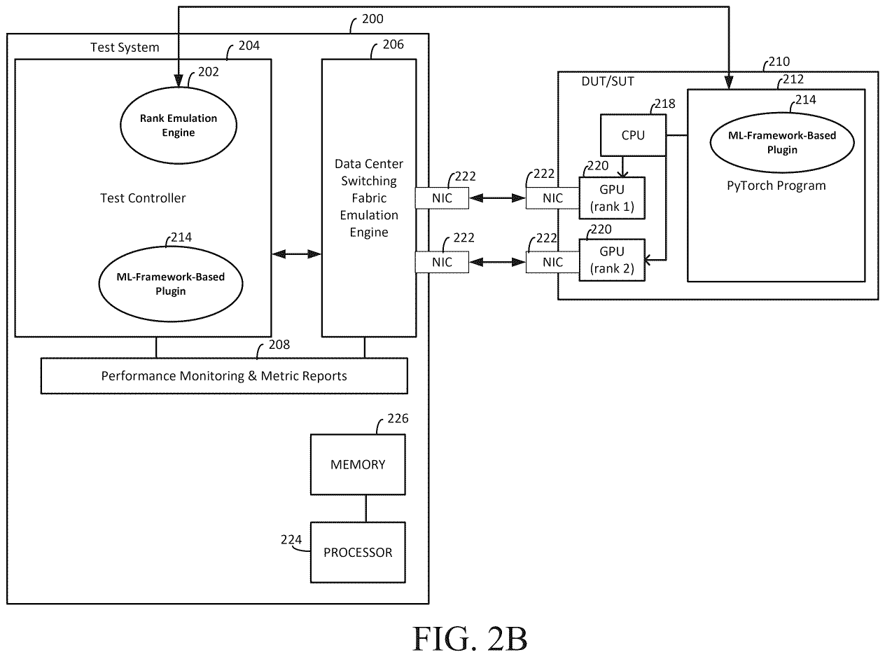

FIGS. 2A and 2B are block diagrams illustrating a system for testing the performance and reliability of a device or system under test (SUT) using real and emulated processing ranks with emulated and real network communication respectively. Referring to FIG. 2A, a test system 200 includes a test controller 202, running a rank emulation engine 204 that is connected to a data center switching fabric emulation engine 206 and that outputs performance monitoring and metric reports 208. Rank emulation engine 204 can have as few as 3 emulated ranks and more than 500 emulated ranks. A system under test (SUT) 210 is includes a PyTorch program 212 with a custom ML-framework-based plugin 214 and an emulated transport plugin 216 that communicates with test controller 202 via rank emulation engine 204. SUT further includes a central processing unit (CPU) 218 and real ranks 220 that are graphics processing units (GPU) connected to associated network interface cards (NIC) 222. According to this aspect of the subject matter described herein, emulated transport plugin 216 emulates inter-rank communication traffic between the NICs without using an external network.

Referring to FIG. 2B, test system 200 includes a test controller 202, running rank emulation engine 204 that is connected to data center switching fabric emulation engine 206 that is further connected to associated NICs 222 and that outputs performance monitoring and metric reports 208. Test system 200 can also include ML-framework-based plugin 214. Rank emulation engine 204 can have as little as 3 emulated ranks and more than 500 emulated ranks. SUT 210 includes PyTorch program 212 with custom ML-framework-based plugin 214 that communicates with test controller 202 via rank emulation engine 204. SUT 210 further includes CPU 218 and real ranks 220 that are GPUs connected to associated NICs 222. NICs 222 connected to real ranks 220 communicate with NICS 222 connected to data center switching fabric emulation engine 206. Thus, according to this aspect of the subject matter described herein, inter-rank communication traffic between the NICs uses an external network.

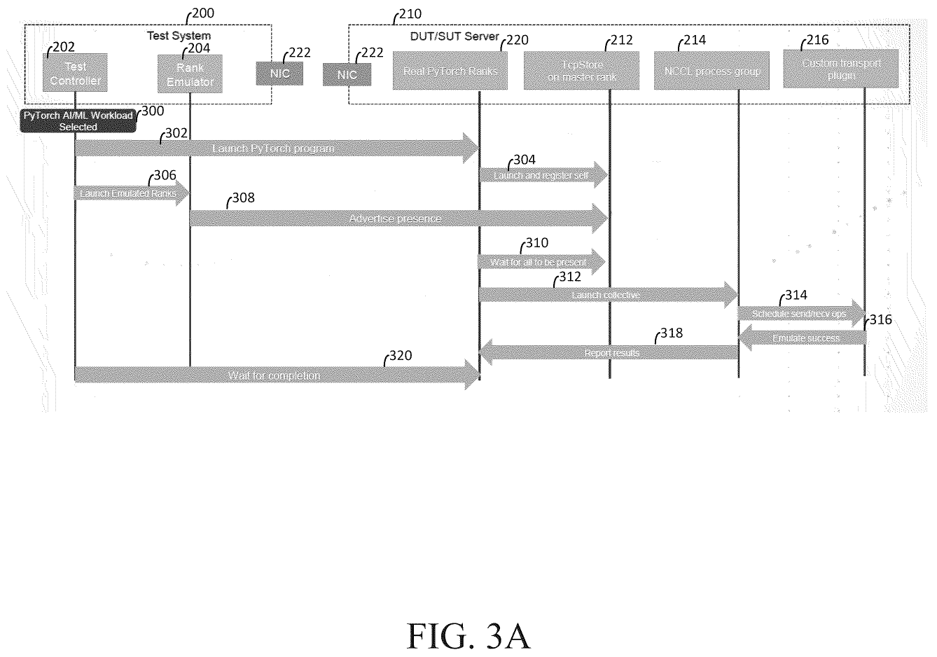

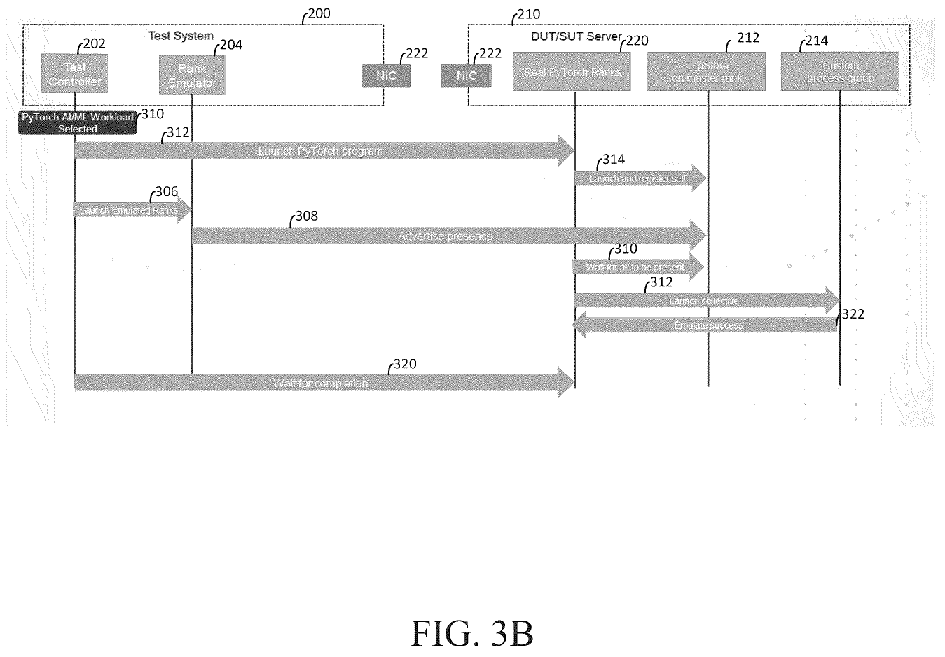

FIGS. 3A and 3B are flow charts illustrating an exemplary process for testing the performance and reliability of a device or system under test (SUT) using real and emulated processing ranks with emulated network communication and real network communication respectively. Referring to FIG. 3A, at step 300, an AI/ML workload is selected on test system 200, and at step 302, test controller 202 launches PyTorch program 212 on SUT 210. At step 304, real ranks 220 launch and register themselves on PyTorch program 212, specifically, a TCPStore on a master rank. At step 306 test controller 202 launches emulated ranks on rank emulation engine 204 that then, in step 308, advertises the presence of the emulated ranks on PyTorch program 212, specifically TcpStore on master rank. At step 310, real ranks 220 wait for all the emulated ranks to be present, and once that occurs, at step 312, real ranks 220 launch collectives on custom ML-framework-based plugin 214 that, at step 314, schedules send and receive operations on emulated transport plugin 216. At step 316, emulated transport plugin 216 then emulates success of the AI/ML workload and communicates it to custom ML-framework-based plugin 214 that, at step 318, reports the results to real ranks 220. At step 320, test controller 202 waits for step 318 to be completed and reported to real ranks 220 upon which it then outputs performance monitoring and metric reports 208.

Referring to FIG. 3B, the only steps that change are due to emulated transport plugin not being used to emulate intra-rank communication. Therefore, starting from step 312, real ranks 220 again launch collectives on custom ML-framework-based plugin 214, however, at step 322, custom ML-framework-based plugin emulates the success of the AI/ML workload rather than emulated transport plugin as shown in FIG. 3A. At step 320, test controller 202 waits for step 322 to be completed and reported to real ranks 220 upon which test controller 202 then outputs performance monitoring and metric reports 208. It should be highlighted that the flowchart illustrated in FIG. 3A, NICs 222 do not communicate with each other, illustrating that inter-rank communication traffic does not use a network and is emulated. Whereas the flow chart illustrated in FIG. 3B, NICs 222 communicate with each other, illustrating that inter-rank communication occurs over a network and is not emulated.

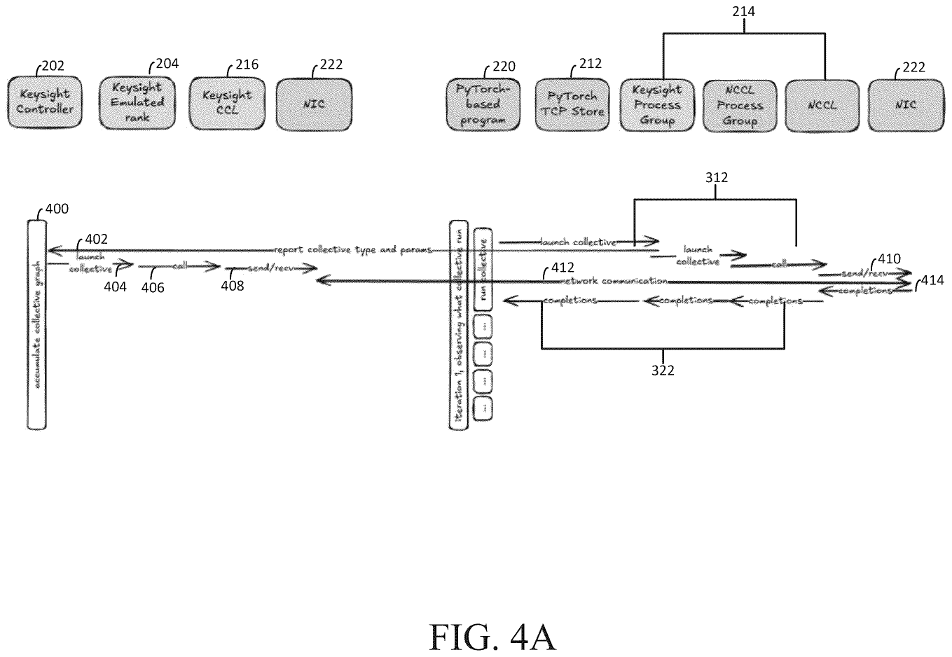

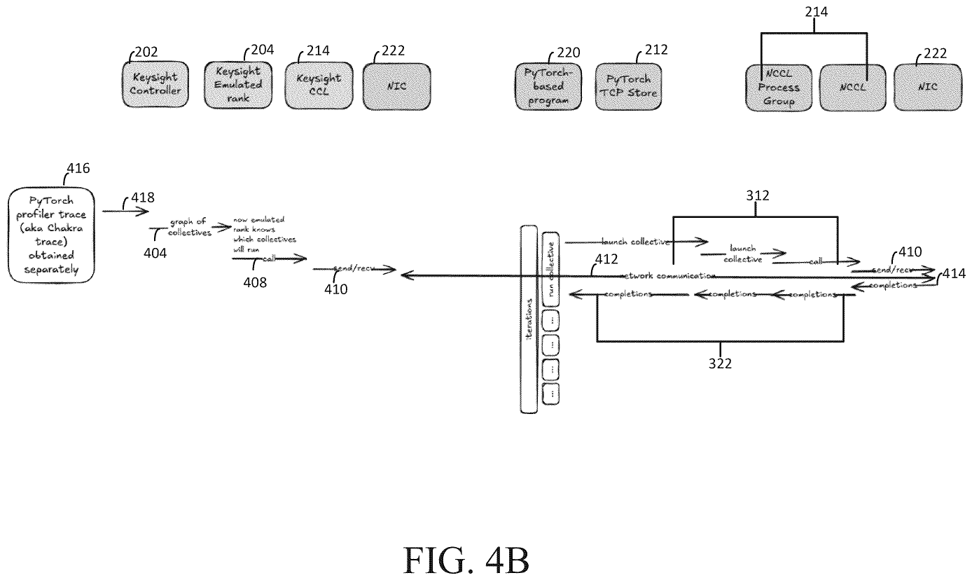

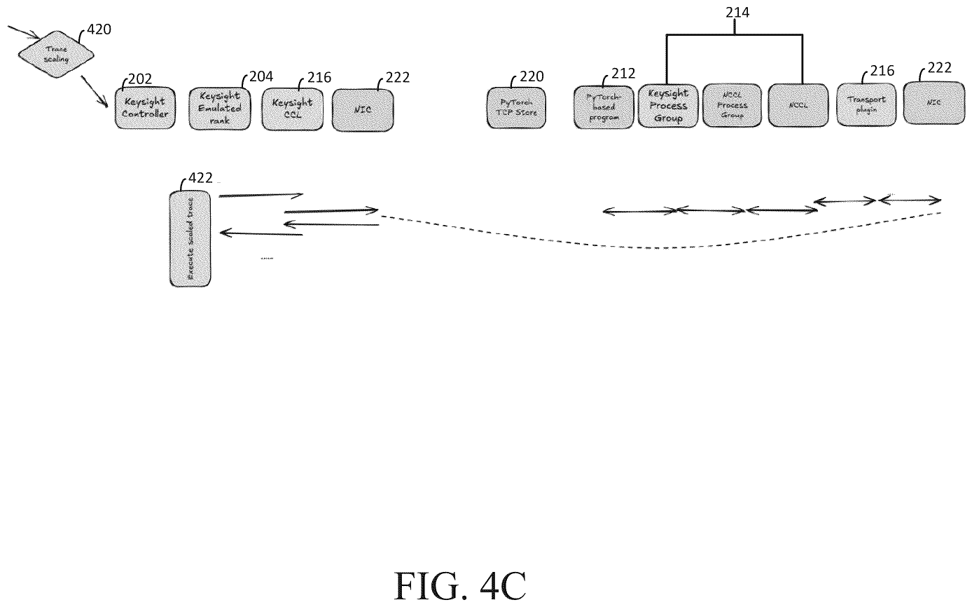

FIGS. 4A, 4B, and 4C are flow charts illustrating an exemplary process for testing the performance and reliability of a device or system under test (SUT) using real and emulated processing ranks using a collective graph, a profile trace, and a scaled profile trace respectively. Referring to FIG. 4A, while performing step 312 (discussed above in reference to FIGS. 3A and 3B), step 400 has test controller 202 accumulate a collective graph and step 402 has test controller 202 report the collective types and parameters to the SUT to facilitate performance of step 312. A collective graph is a structure, showing which rank communicates with which rank, in what order, and over which data links. Control then passes to step 404 where test controller 202 launches the collective on rank emulation engine 204 where, at step 406, rank emulation engine 204 calls ML-framework plugin 214 on test system 200 that, at step 408, use NIC 222 on test system 200 to communicate network communication with NIC 222 on SUT 210. After test controller 202 performs steps 400 through 402 to facilitate completion of step 312, and at the same time as test controller 202 is performing steps 404 through 408, SUT 210, at step 410, performs send and receive operations between ML-framework-based plugin 214 on SUT 210 and the associated NIC 222 on SUT 210. At step 412, NIC 222 on test system 200 and NIC 222 on SUT 210 communicate over the network, upon which at step 414 NIC 222 on SUT 210 reports completion to ML-framework-based plugin 214 on SUT 210 that then performs step 322 referenced in FIG. 3B. Steps 400 through 414 using accumulated collective graph can be iterated through as the training process consists of several iterations which are identically structured. Therefore, after one iteration finishes, accumulated information can be used to launch collectives by repeating the sequence observed from the first iteration, eliminating the overhead of the observer to enable execution at full performance.

Referring to FIG. 4B, at step 416 a profile trace obtained separately is sent, at step 418, to test controller 202. The profile trace is now used as input as the graph of collectives for steps 404 through 414 as referenced in FIG. 4A. This allows a graph of collectives to be executed by passing the trace to test controller 202 and then to rank emulation engine 204 allowing it to perform operations that a rank executing a real PyTorch-based program would emulate presence of multiple ranks in addition to real ones.

Referring to FIG. 4C, after the profile trace, referenced in FIG. 4B, is performed, it can be used, in step 420, as input to a scaled version of the system with more emulated ranks than what was originally tested. This scaled version, at step 422, is sent from test controller 202 to rank emulation engine 204, and steps 404 through 414, as referenced in FIG. 4A, are repeated. The scaling logic generates a new trace for a much higher training cluster scale ranks based on knowledge of algorithm behaviors supported by PyTorch and CCL at a different number of ranks participating in the training job that is sought to be emulated. Scaled trace is then provided to test controller 202 and rank emulation engine 204 to efficiently execute send/receive operations against ranks executing real PyTorch-based program.

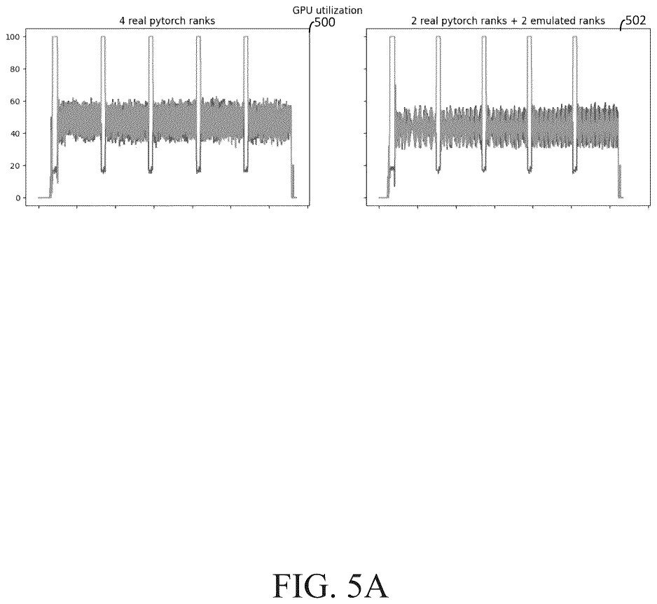

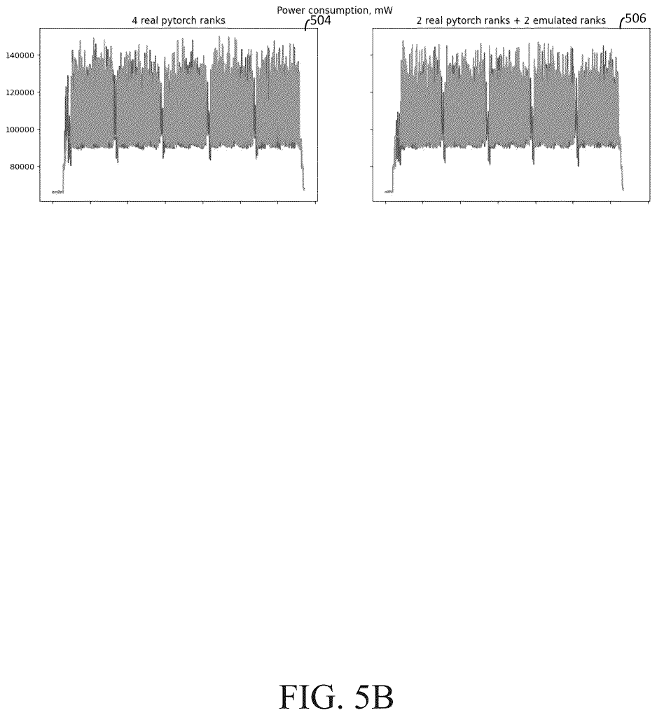

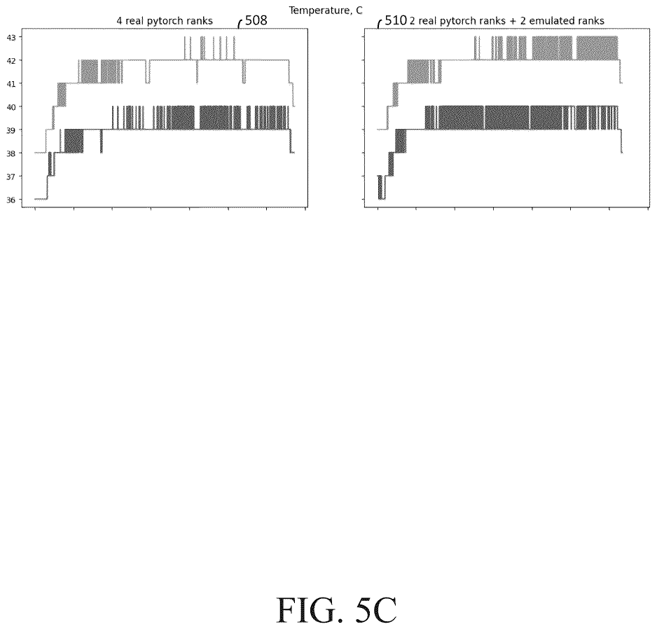

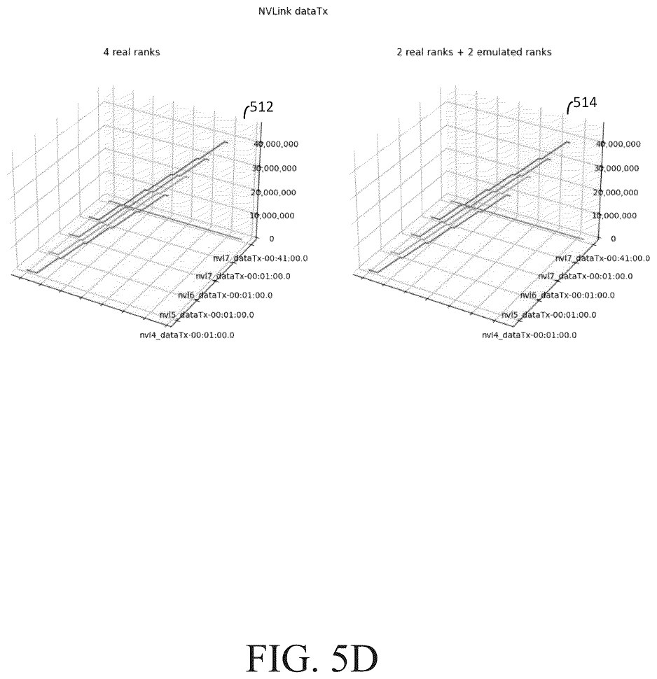

FIGS. 5A, 5B, 5C, and 5D are diagrams comparing the accuracy of a system that consists of two real ranks and two emulated ranks with a system consisting of four real ranks in GPU utilization, power consumption, temperature, and NVLink data transfers. In each of FIGS. 5A, 5B, 5C, and 5D, SUT 210 includes four real ranks 220 consisting of GPUs or two real ranks 220 and two emulated ranks, emulated by rank emulation engine 204, and such that SUT 210 sees itself as just part of a cluster. SUT 210 communicates with test system 200 using data center switching fabric emulation engine 206 and emulated transport plugin 216 as illustrated in FIG. 2A. Referring to FIG. 5A, graph 500 illustrates real GPU utilization and graph 502 illustrates partially emulated GPU utilization. Graphs 500 and 502 illustrate that the system with two emulated ranks performs comparably to the system with only real ranks.

Referring to FIG. 5B, graph 504 illustrates real power consumption and graph 506 illustrates partially emulated power consumption. Graphs 504 and 506 illustrates that the system with emulated ranks has comparably the same amount of power draw as the system with only real ranks.

Referring to FIG. 5C, graph 508 illustrates real temperature and graph 510 illustrates partially emulated temperature. Graphs 508 and 510 illustrate that the system with emulated ranks comparably has the same temperatures and temperature spikes/fluctuations as the system with only real ranks.

Referring to FIG. 5D, graph 512 illustrates real NVLink data transfers and graph 514 illustrates partially emulated NVLink data transfers. Graphs 512 and 514 illustrate that data transfers for each of the ranks in the system with emulated ranks is comparable to data transfers for each of the ranks in the system with only real ranks.

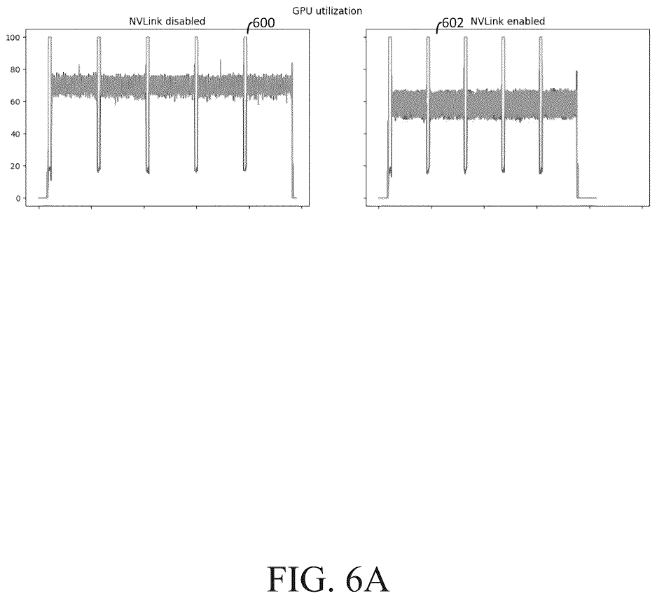

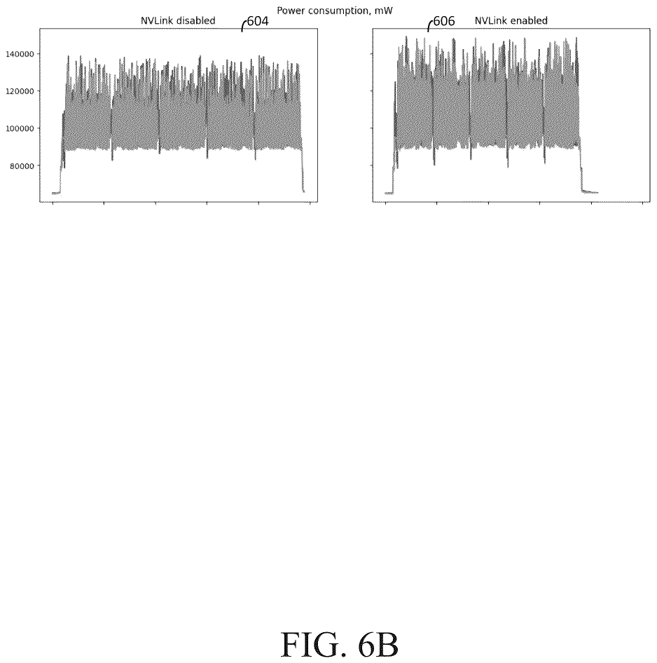

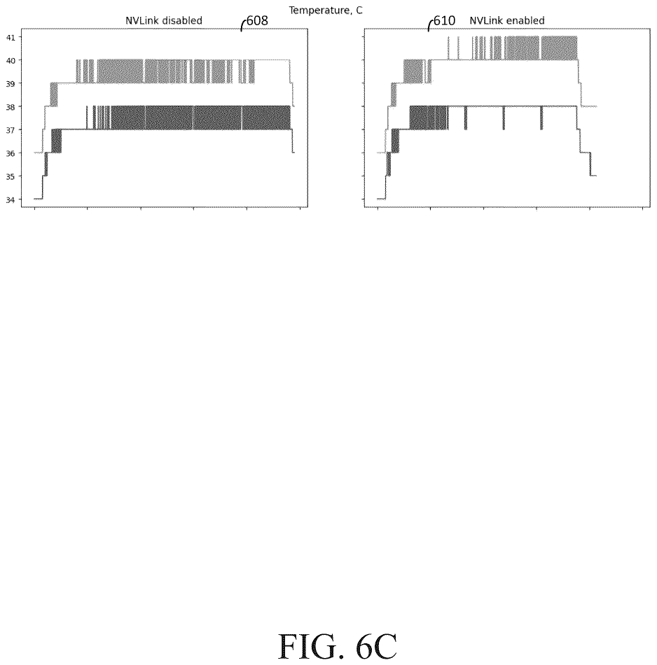

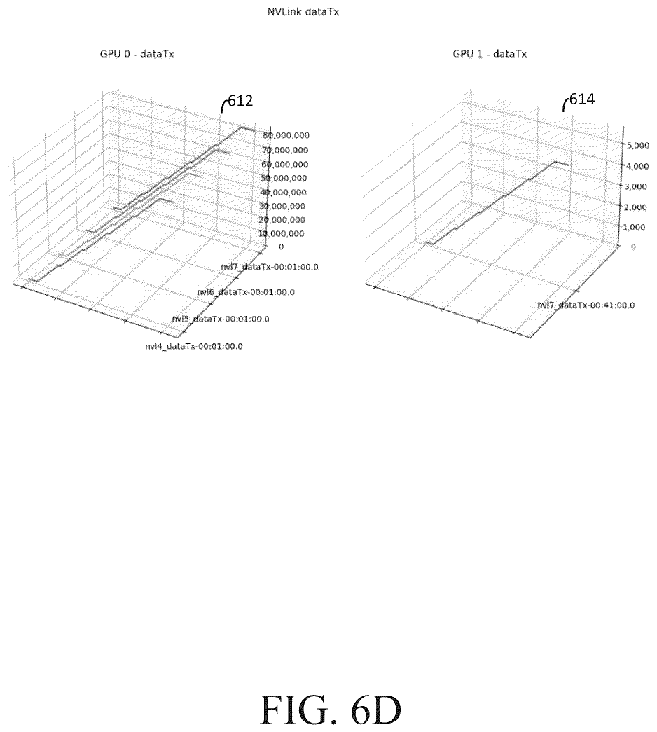

FIGS. 6A, 6B, 6C, and 6D are diagrams comparing the results of a system utilizing four real ranks and twelve emulated ranks that has NVLink enabled with a system utilizing four real ranks and twelve emulated ranks that has NVLink disabled in GPU utilization, power consumption, temperature, and data transfers. Referring to FIG. 6A, graph 600 illustrates GPU utilization with NVLink disabled and graph 602 illustrates GPU utilization with NVLink enabled.

Referring to FIG. 6B, graph 604 illustrates power consumption with NVLink disabled and graph 606 illustrates power consumption with NVLink enabled.

Referring to FIG. 6C, graph 608 illustrates temperature with NVLink disabled and graph 610 illustrates temperature with NVLink enabled.

Referring to FIG. 6D, graph 612 illustrates data transfers with NVLink enabled and graph 614 illustrates data transfer with NVLink disabled.

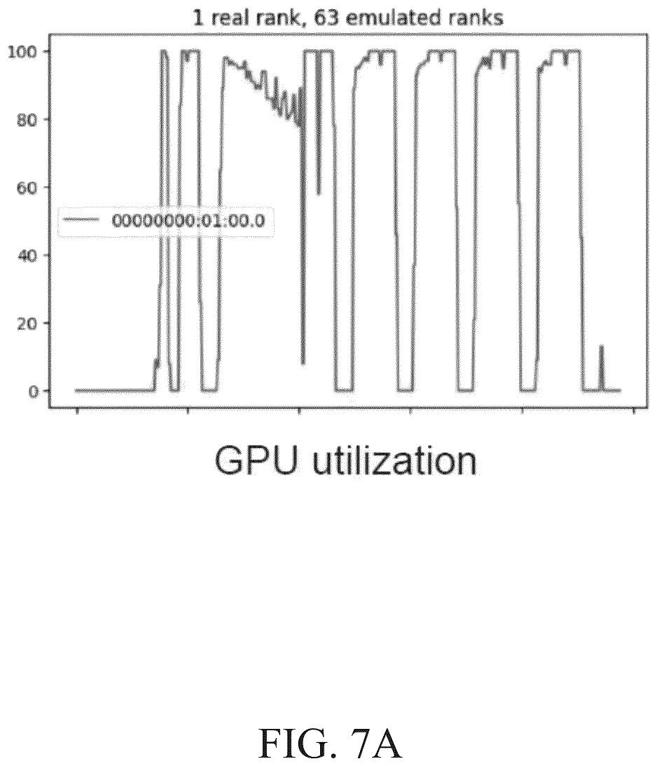

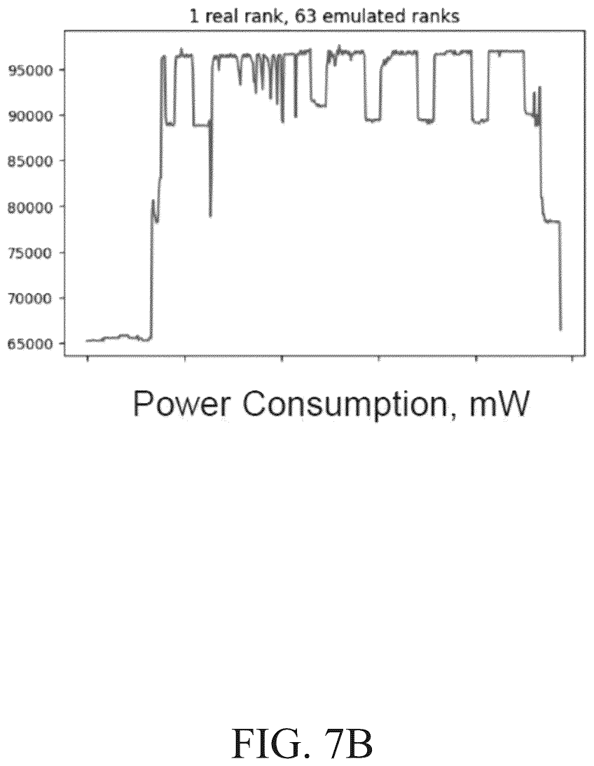

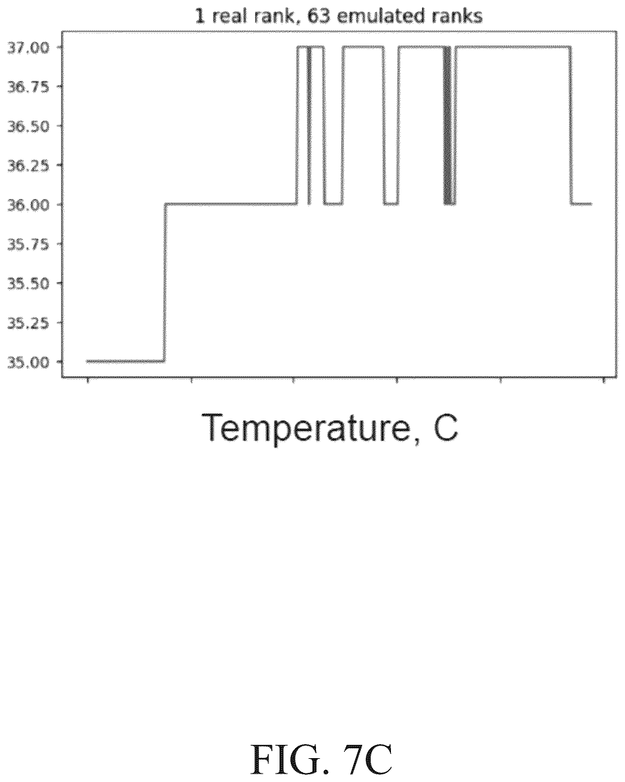

FIGS. 7A, 7B, and 7C are diagrams illustrating the GPU utilization, power consumption, and temperature of a system with one real rank and 63 emulated ranks respectively.

It will be understood that various details of the subject matter described herein may be changed without departing from the scope of the subject matter described herein. Furthermore, the foregoing description is for the purpose of illustration only, and not for the purpose of limitation.

What is claimed is:

1. A method for testing the performance and reliability of a device or system under test (SUT) using real and emulated processing ranks within a data center environment, the method comprising:
connecting a test system to a SUT, the test system comprises a controller and the SUT comprises non-emulated processing units;
instantiating a machine learning (ML)-framework-based plugin comprising an emulator configured for emulating processing units;
communicating, from the controller on the test system, a configuration of the ML-framework-based plugin to non-emulated processing units comprising a collectives parameter indicating a quantity and rank information of the emulated processing units;
performing a test of the SUT by:
executing a ML workload on the non-emulated processing units;
emulating execution of the ML workload on the emulated processing units;
exchanging packets associated with the execution of the ML workload between the non-emulated processing units and the ML-framework-based plugin; and
monitoring performance of the non-emulated processing units in executing the ML workload.

2. The method of claim 1 comprising instantiating, on the SUT, an emulated transport plugin, wherein instantiating the ML-framework-based plugin comprises instantiating the ML-framework-based plugin on the SUT and exchanging the packets comprises emulating, using the emulated transport plugin, transport of the packets over a network.

3. The method of claim 2 wherein the emulated transport plugin comprises a collective communications library (CCL) plugin.

4. The method of claim 2 comprising using the emulated transport plugin to control an execution graph implemented by the emulated and non-emulated processing units.

5. The method of claim 1 wherein instantiating the ML-framework-based plugin comprises instantiating the ML-framework-based plugin on the test system and exchanging the packets comprises exchanging packets between the test system and the non-emulated processing units over a network.

6. The method of claim 1 comprising adjusting the collectives parameter during the execution of the ML workload.

7. The method of claim 6 wherein adjusting the collectives parameter comprises changing the quantity of emulated processing units.

8. The method of claim 1 wherein the ML-framework-based plugin comprises a PyTorch plugin, a Scikit-learning plugin, or a Tensorflow plugin.

9. The method of claim 8 wherein the ML-framework plugin comprises the PyTorch plugin and wherein emulating the processing units comprises interacting with a TCPStore.

10. The method of claim 1 wherein emulating the processing units comprises emulating at least one rack of processing units that, when combined with the non-emulated processing units, form a cluster of processing units.

11. A system for testing the performance and reliability of a device or system under test (SUT) using real and emulated processing ranks within a data center environment, the system comprising:
a test system comprising a controller, at least one processor and a memory, and a connector for connecting to an electrical connector associated with a SUT comprising non-emulated processing units, and is configured to perform a test of the SUT comprising computer-executable instructions stored in the memory and executable by the at least one processor by instantiating a machine learning (ML)-framework-based plugin comprising an emulator configured for emulating processing units;
communicating, from the controller on the test system, a configuration of the ML-framework-based plugin to non-emulated processing units comprising a collectives parameter indicating a quantity and rank information of the emulated processing units;
performing the test of the SUT by:
executing a ML workload on the non-emulated processing units;
emulating execution of the ML workload on the emulated processing units;
exchanging packets associated with the execution of the ML workload between the non-emulated processing units and the ML-framework-based plugin; and
monitoring performance of the non-emulated processing units in executing the ML workload.

12. The system of claim 11 configured for instantiating, on the SUT, an emulated transport plugin, wherein instantiating the ML-framework-based plugin comprises instantiating the ML-framework-based plugin on the SUT and exchanging the packets comprises emulating, using the emulated transport plugin, transport of the packets over a network.

13. The system of claim 12 wherein the emulated transport plugin comprises a collective communications library (CCL) plugin.

14. The system of claim 12 configured for using the emulated transport plugin to control an execution graph implemented by the emulated and non-emulated processing units.

15. The system of claim 11 wherein instantiating the ML-framework-based plugin comprises instantiating the ML-framework-based plugin on the test system and exchanging the packets comprises exchanging packets between the test system and the non-emulated processing units over a network.

16. The system of claim 11 configured for adjusting the collectives parameter during the execution of the ML workload and comprises changing the quantity of emulated processing units.

17. The system of claim 11 wherein the ML-framework-based plugin comprises a PyTorch plugin, a Scikit-learning plugin, or a Tensorflow plugin.

18. The system of claim 17 wherein the ML-framework plugin comprises the PyTorch plugin and wherein emulating the processing units comprises interacting with a TCPStore.

19. The system of claim 11 wherein emulating the processing units comprises emulating at least one rack of processing units that, when combined with the non-emulated processing units, form a cluster of processing units.

20. A non-transitory computer readable medium having stored thereon executable instructions that when executed by a processor of a computer control the computer to perform steps comprising:
instantiating a machine learning (ML)-framework-based plugin comprising an emulator configured for emulating processing units;
communicating, from a controller on a test system, a configuration of the ML-framework-based plugin to non-emulated processing units on a SUT comprising a collectives parameter indicating a quantity and rank information of the emulated processing units;
performing a test of the SUT by:
executing a ML workload on the non-emulated processing units;
emulating execution of the ML workload on the emulated processing units;
exchanging packets associated with the execution of the ML workload between the non-emulated processing units and the ML-framework-based plugin; and
monitoring performance of the non-emulated processing units in executing the ML workload.
